(19) United States
(12) Patent Application Publication
(10) Pub. No.: US 2001/0036278 A1
(43) Pub. Date: Nov. 1, 2001

(54) Ultra bass II

(76) Inventors: Catherine Polisset, Leuven (BE); Hang Meng Teo, Leuven (BE); Loic Bernard Tanghe, Leuven (BE); Renaud Marc Odette Saint Moulin De, Leuven (BE)

Correspondence Address: Michael E. Marion, U.S. Philips Corporation, 580 White Plains Road, Tarrytown, NY, 10591, US

(21) Appl. No.: 09/829,791

(22) Filed: Apr. 10, 2001

(30) Foreign Application Priority Data
Apr. 11, 2000 (EP) 00201302.7

(51) Int. Cl. H03G 3/00

(52) U.S. Cl. 381/61

(57) ABSTRACT

Audio systems are known and are used to reproduce audio signals from for example prerecorded CDs or to reproduce received radio signals.

To improve the signals especially in the lower frequency range so called ultra bass is known. The invention proposes to further improve the signals in the low frequency range by introducing a feed forward control to overcome problems with supplying signals in the low frequency range with a volume that would overdrive the loudspeakers.

The invention relates to an audio system as described in the preamble of claim 1.

The invention further relates to enhancing means for use in such an audio system.

High fidelity reproduction of audio signals ideally requires sound transducers capable of reliably reproducing sounds throughout the listening range of the human beings. This has been determined to be 20-20.000 Hz. However, realistically, most high fidelity speaker systems are capable of reproducing sounds in the frequency range of 40-20.000 Hz. These high fidelity systems include small transducers (tweeters) for reproducing the high end of the frequency range, and relatively large transducers (woofers) for reproducing the low end of the frequency range. Naturally these speaker systems are large in size and take up a substantially amount of space in the listening area.

However, there are many customers who enjoy high fidelity sound but do not have the space for a high fidelity speaker system. Manufacturers recognizing this problem have been marketing compact audio systems with small speaker systems for these consumers. However in view of the relatively small size of the speaker systems, these small speaker systems are not capable of reproducing audio frequencies in the range of 40-100 Hz. The consumer using these compact audio systems is then able to notice this deficiency and are then disappointed with the system.

Such an audio system is known from the European patent application EP-A-0546619 (applicants reference PHA40624). Since the invention of the electrodynamics loudspeaker, there is a need for greater acoustical output, especially at low frequencies. Often however, for instance in television sets or portable audio sets, this acoustical output is severely limited by the small size of the loudspeakers. It is known that this dilemma can be solved by using a psycho-acoustic phenomenon often referred to as virtual pitch or missing fundamental, which evokes the illusion of a higher bass-response, while the loudspeaker does not radiate more power at these low frequencies. This illusion can be created by replacing low-frequency tones, which are present in the audio signal but can not reproduced by a small loudspeaker, by harmonics of these tones. The harmonics now represent the low-frequency tones, the so-called ultra bass.

In the known audio system a low-frequency band of an audio signal is selected and supplied to enhancing means in the form of a harmonics generator for generating harmonics of the selected signal. The generated harmonics are thereafter added to the audio signal. In this way the low-frequency perception of the audio signal is improved. In the known audio system a full wave rectifier is used as harmonics generator, which generates only even harmonics.

An objective is to reduce the artefacts and so have a more natural effect, increase the music range efficiency and have as much as possible of the effect quantity. An other objective is to have an adaptive system to optimize the headroom available and avoid distortion at maximum volume.

A further object of the invention is to further improve the perceived low frequency audio signals.

To this end a first aspect of the invention provides an audio system as defined in claim 1.

The invention is based on the inside that to overcome the problem of generating too much signals in the low frequency band it is much more effective to use a feed forward automatic gain control to control the gain of the harmonics generator dependent on the received input signal then to only try to reduce the level of low frequency signals at the end of the enhancing means.

Embodiments of an audio system according to the invention are described in the dependent claims.

The invention and additional features, which may optionally be used to implement the invention to advantage, will be apparent from and elucidated with reference to the examples described below and hereinafter and shown in the figures. Herein shows:

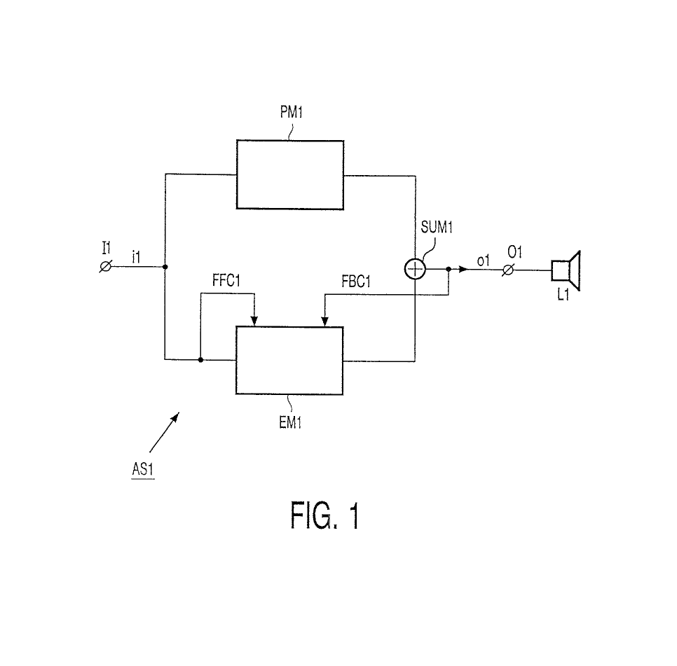

FIG. 1 a schematic embodiment of an audio system according to the invention,

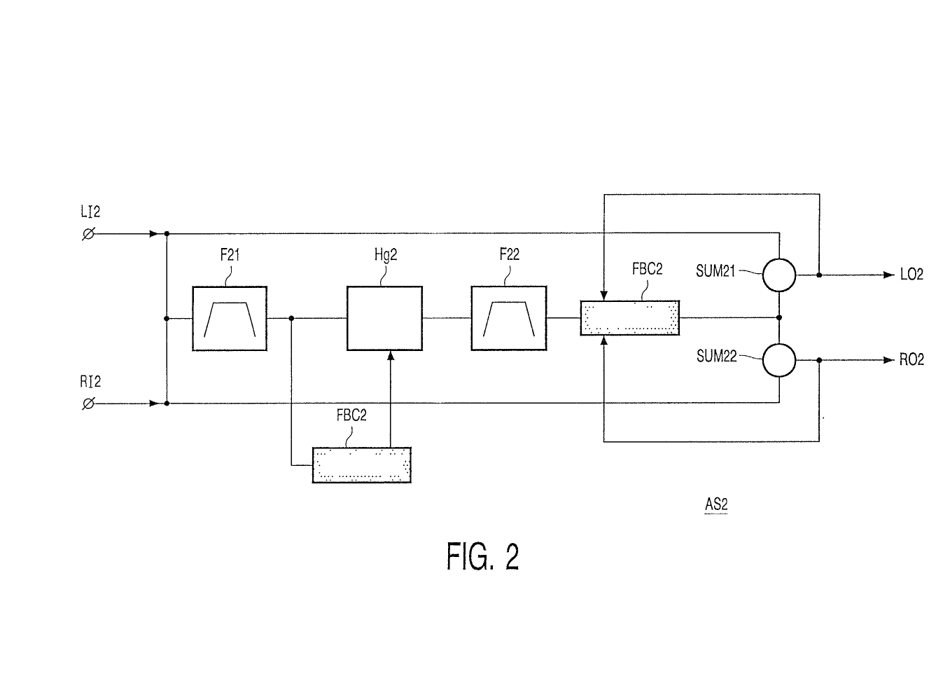

FIG. 2 a second schematic embodiment of an audio system according to the invention and

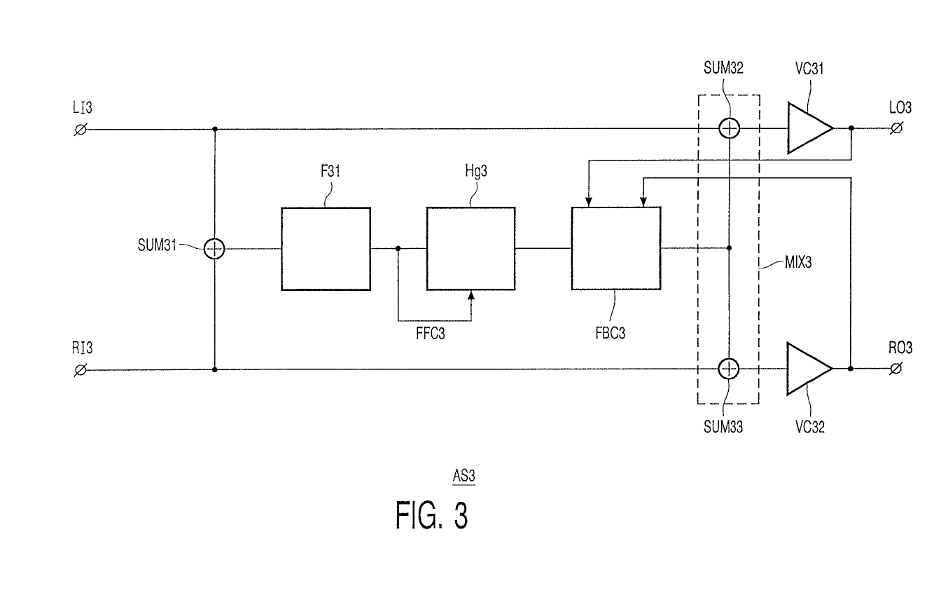

FIG. 3 an embodiment of enhancing means according to the invention.

Corresponding elements will be referred to with corresponding reference signs throughout the figures.

FIG. 1 shows a schematic embodiment of an audio system AS 1, comprising processing means PM1 and enhancing means EM1. In this example only one input signal i1 and one output signal o1 is shown. Of course the same technology can be used with stereo or multi channel applications (see for example FIG. 2 for a stereo application). The audio system further comprises an input I1 for receiving an audio input signal i1 and an output O1 for supplying an audio output signal o1 for example to be supplied to a loudspeaker L1. The processing means and the enhancing means are both coupled to the input for receiving the audio input signal. The outputs of the processing means and of the enhancing means are coupled to respective inputs of summing means SUM1 for summing the processed signals and supplying the combined signal to the output O1.

The operation of the audio system AS1 is as follows. The received input signal i1 is processed in the processing means PM1 as is normally done in an audio system, which is known to the man skilled in the art and needs no further explanation. The enhancing means EM1 will select a frequency range from the input signal i1, which has to be processed separately, and afterwards being added in the adding means AM1 to the processed signal. The enhancing means EM1 comprise both a feed forward control FFC1 from the input of the enhancing means EM1 and a feedback control FBC1 from the output O1 of the audio system AS1.

To overcome the problem of generating too much signals in the low frequency band it is much more effective to use a feed forward automatic gain control to control the gain of the harmonics generator dependent on the received input signal then to only try to reduce the level of low frequency signals at the end of the enhancing means.

In the following the operation of the enhancing means according to the invention will be described in more detail with reference to the further figures.

FIG. 2 shows a second schematic embodiment of an audio system AS2 comprising two inputs LI2, RI2. Both inputs are coupled to first filter means F21 for filtering the input signal to select the lower part of the frequency band to be enhanced (improved). This lower part is supplied to an harmonics generator HG2 which further receives a signal from a feed forward control FFC2 from the output of the first filter means F21. The output of the harmonics generator HG2 is coupled via second filter means F22 to a feedback control means FB2 which receives from both a left output LO2 and a right output RO2 a feedback signal. The output of the feedback control means FBC2 is coupled via respectively a first summing means SUM21 and a second summing means SUM22 to the output LO2 respectively RO2.

The processing of the “normal” left and right audio signals in the processing means (see FIG. 1; PM1) is not shown in this figure.

FIG. 3 shows a third schematic embodiment of an audio system AS3 which third embodiment is an analog version of the digital version of FIG. 2. This audio system comprises a first and a second input LI3, RI3 and a first and a second output LO3, RO3. The inputs are coupled to a summing device SUM31 for summing the left and right input signal and supplying a combined signal to first filter means F31. In this filter means the input signal is filtered to obtain only the low frequency component to be enhanced. The output of the filter means F31 is coupled to an harmonics generator HG3 for creating harmonics of the received low pass filtered input signal. The output of the filter means F31 is also coupled to the harmonics generator HG3 to supply a feed forward control signal FFC3. The output of the harmonics generator is coupled to feedback control means FBC3. The output of the harmonics generator is coupled to mixing means MIX3 in this example indicated by two summing means SUM32 and SUM33. In the mixing means the output signal of the feedback control means FBC3 is combined with respectively the “normal” left input signal and with the “normal” input signal. The outputs supply the respectively output signals which are supplied via volume control means VC31, VC32 to respectively the left output LO3 and the right output RO3.

The output signals are also supplied as feed back signals to the feed back control means FBC3.

The harmonics generator can be implemented with so called OPAMPs, resistors and capacitors.

It is to be noticed that in the “normal” signal path of the audio signal(s) high pass filters can be incorporated to improve the performance of the audio system. For example these filters can be used to protect small loudspeakers. It helps to prevent overdriving of the loudspeakers below its resonance frequency. For bigger loudspeakers, so with less problems of overdriving, these filters can be removed to enhance the timbre of the low frequencies present in the input signal.

The mixing means MIX3 can be used to regulate the amount of low frequency signal to be added to the “normal” audio signal.

1. Audio system comprising an input for receiving an audio signal and an output for supplying an output signal, processing means for processing the received audio signal and enhancing means, whereby the enhancing means comprise selecting means for selecting a part of the audio signal, and an harmonics generator for generating harmonics of the selected part of the audio signal, characterized in that the enhancing means further comprise a feed forward automatic gain control to control the gain of the harmonics generator dependent on the received input signal.

2. Audio system as claimed in claim 1, characterized in that the audio system comprises low pass filter means to select a low part of the audio signal to be enhanced coupled between the input and the enhancing means and the feed forward control automatic gain control is coupled from the output of the low pass filter means to a control input of the enhancing means.

3. Audio system according to claim 1, characterized in that the enhancing means comprise a feed back control to control the gain of the harmonics generator dependent on the output audio signal coupled between the output of the audio system to a control input of the enhancing means.

4. Enhancing means for use in an audio system as claimed in claim 1.
